(19) United States
(12) Patent Application Publication
(10) Pub. No.: US 2002/0081836 A1
(43) Pub. Date: Jun. 27, 2002

(54) Contact structure, semiconductor device and manufacturing method thereof

(75) Inventors: Hiroki Takewaka, Tokyo (JP); Takao Kamoshima, Tokyo (JP); Junko Izumitani, Tokyo (JP)

Correspondence Address: McDermott, Will & Emery, 600 13th Street, N.W., Washington, DC, 20005-3096, US

(73) Assignee: MITSUBISHI DENKI KABUSHIKI KAISHA

(21) Appl. No.: 09/858,638

(22) Filed: May 17, 2001

(30) Foreign Application Priority Data
Dec. 25, 2000 (JP) 2000-393077

(51) Int. Cl. H01L 21/4763; H01L 21/44

(52) U.S. Cl. 438/637; 438/672; 438/675

(57) ABSTRACT

There are provided a cell plate layer 5 formed in the insulating films 10 and 11 on a semiconductor substrate 4. A connecting hole 12 is formed through the insulating films 10 and 11 and the cell plate layer 5, and the circumference of the side surface of the cell plate layer is exposed. A conducting plug 7A is formed by filling the connecting hole 12 with a conductor so as to contact the circumference of the side surface, for example, an upper surface of the cell plate layer 5. By increasing a contact area between a conductor layer and a conducting member, a contact resistance is lowered, and a stable and reliable semiconductor device is obtained.

### BACKGROUND OF THE INVENTION

1. Field of the Invention

The present invention relates to a semiconductor device and a manufacturing method of the semiconductor device, and a contact structure and a forming method of the contact structure. More specifically, the present invention relates to a wiring structure of a semiconductor integrated circuit device in which a connecting hole or a wiring groove filled with a conductor is connected to a conductor layer in an insulating film at the side wall thereof, and a method for manufacturing such a wiring structure.

2. Background Art

Currently, in a semiconductor integrated circuit, particularly in a DRAM, electrical contact must be established between a metal wiring layer and a bit wiring layer or cell plate layer in an interlayer insulating film.

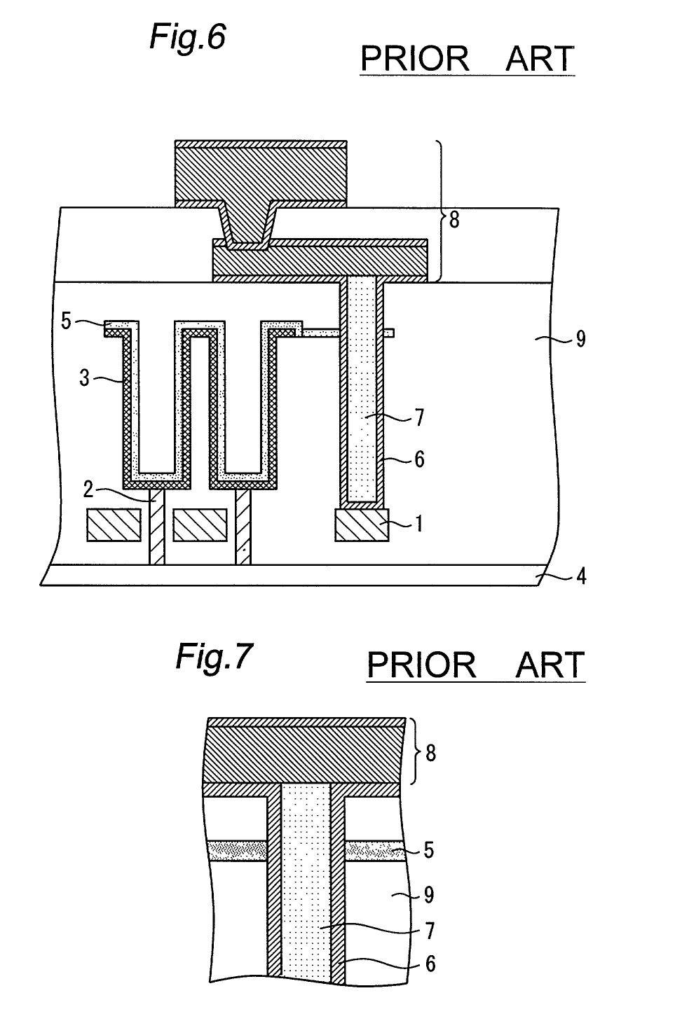

FIG. 6 is a cross-sectional view showing a conventional semiconductor integrated circuit device.

In FIG. 6, reference numeral 1 is a bit line of tungsten as a bit-line wiring layer, 2 is a connecting hole between a storage node layer 3 and a silicon semiconductor substrate 4, 5 is a cell plate layer as a conductor layer, 6 is a barrier metal of a titanium nitride film as a diffusion preventing layer, 7 is a conductor plug of tungsten as a conductor, 8 is an aluminum wiring layer as a metal wiring layer, and 9 is an interlayer insulating film.

In such a semiconductor integrated circuit device, the conductor plug 7 filled with a conductor connects the metal wiring layer 8 and the bit-line wiring layer 1. Further, a structure has been developed, in which the conductor plug 7 contacts the cell-plate layer 5 at the sidewall thereof.

FIG. 7 is a schematic sectional view showing a conductor plug 7 filled with a conductor, and a conductor layer 5 that is connected to the sidewall of the conductor plug 7. In FIG. 7, the same reference numerals are used for components corresponding to components shown in FIG. 6, and such components are not described in detail.

### SUMMARY OF THE INVENTION

However, in the conventional semiconductor integrated circuit device as described above, the decrease in the thickness of the cell plate layer or the reduction of the conductor plug diameter reduces the contact area therebetween, so that a problem has arose in that a stable and low contact resistance is difficult to achieve.

The object of the present invention is to solve such a problem, and to provide a contact structure and a method for forming such a contact structure, and a semiconductor device that has a stable and low contact resistance and a method for manufacturing such a semiconductor device.

According to one aspect of the present invention, a semiconductor device comprises a semiconductor substrate, an insulating film formed on the semiconductor substrate, and a conductor layer formed in said insulating film. A through hole is formed through said insulating film and said conductor layer so as to expose a circumference of the side surface of said conductor layer, and a conducting member is provided by filling said through hole with a conductor.

According to another aspect of the present invention, in a method of manufacturing a semiconductor device, a first insulating film is formed on a semiconductor substrate. A conductor layer is formed on said first insulating film, and a second insulating film is formed on said conductor layer. A through hole is formed passing through said second insulating film, said conductor layer, and said first insulating film. At least one of said first and second insulating films is retracted in said through hole to expose said conductor layer, and said through hole is filled with a conductor to form a conducting member.

Other and further objects, features and advantages of the invention will appear more fully from the following description.

### DETAILED DESCRIPTION OF THE PREFERRED EMBODIMENTS

Some embodiments of the present invention applied in a semiconductor integrated circuit device will be described below referring to the drawings. In the drawings, the same portions or components are designated by the same reference numerals and the duplicated explanation may be simplified or omitted.

First Embodiment

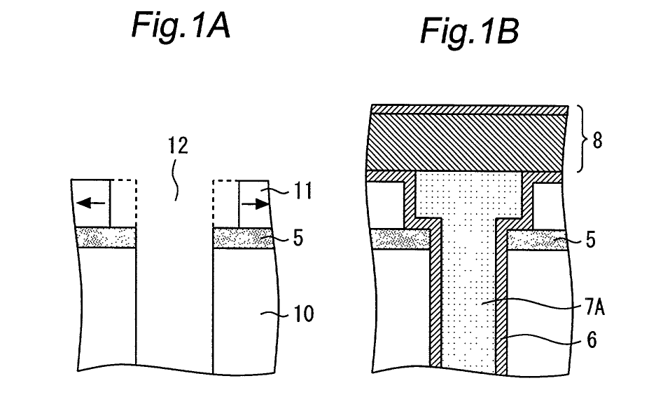

FIGS. 1A and 1B are a schematic cross-sectional views showing a conductor plug filled with a conductor, and a conductor layer that is connected to a sidewall of the conductor plug according to a First Embodiment of the present invention. FIG. 1A is a sectional view when the conductor plug is not yet formed by filling the conductor, and FIG. 1B is a sectional view after the conductor plug has been formed.

In FIGS. 1A and 1B, reference numeral 5 designates cell plate layer as a conductor layer, 6 is a barrier metal of a titanium nitride film as a diffusion preventing layer, 7A is a conductor plug of tungsten as a conductor member, 8 is an aluminum wiring layer as a metal wiring layer, and 10 and 11 designate respectively a first and a second interlayer insulating film, and 12 is a connecting hole or a through hole for connecting the aluminum wiring layer 8 with the conductor plug 7A. Here, the insulating film 11 has a larger etchability, i.e. a higher etch rate, than the insulating film 10.

In the First Embodiment, the second insulating film 11 on the upper surface of the conductor layer 5 is retracted to expose the surface of the conductor layer 5 to increase the contact area.

Next, the manufacturing process of the First Embodiment will be described below.

First, different insulating films are laminated on the upper and lower surfaces of the cell plate layer 5 that is to be connected to the sidewall of the conductor plug 7A filled with tungsten. Here, the first insulating film 10 having a smaller etchability is formed on the lower surface of the cell plate layer 5, and the second insulating film 11 having a larger etchability is formed on the upper surface of the cell plate layer 5.

Next, the connecting hole 12 is formed using anisotropic etching, then, the laminate is immersed in a chemical solution that etches only the second insulating film 11 on the upper surface of the cell plate layer 5 to retract the second insulating film 11 in the lateral direction shown by arrows until the upper surface of the cell plate layer 5 is exposed (see FIG. 1A).

Next, the barrier metal 6 is formed on the inner wall of the connecting hole 12, and then the connecting hole is filled with tungsten to form the conductor plug 7A as a conductor member. At this time, the conductor plug 7A contact substantially not only with the sidewall but also with the upper surface of the cell plate layer 5 (see FIG. 1B). Therefore, the contact area increases and the resistance lowers.

According to the First Embodiment, as described above, the insulating film on the upper surface of the cell plate layer is retracted to increase the contact area between the cell plate layer and the conductor plug filled with tungsten, thus lowering contact resistance.

Second Embodiment

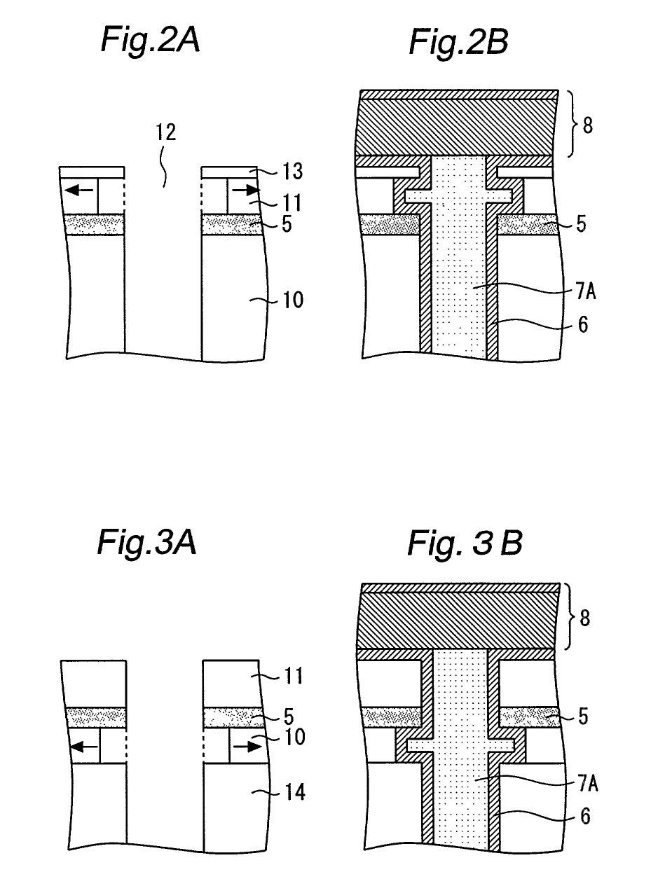

FIGS. 2A and 2B are schematic sectional views showing a conductor plug filled with a conductor, and a conductor layer that is connected to the sidewall of the conductor plug according to a Second Embodiment of the present invention. FIG. 2A is a sectional view when the conductor plug is not yet formed by filling the conductor, and FIG. 2B is a sectional view after the conductor plug has been formed.

In FIGS. 2A and 2B, reference numeral 13 indicates a third insulating film formed on the upper surface of the second insulating film 11. Other components are same as the components shown in FIG. 1. Here, the second insulating film 11 has a larger etchability, i.e. a higher etch rate, than the first and third insulating films 10 and 13, respectively.

In the Second Embodiment, the second insulating film on the upper surface the conductor layer 5 is selectively retracted to expose the surface of the conductor layer 5 to increase the contact area.

Next, the manufacturing process of the Second Embodiment will be described below.

First, different insulating films are laminated on the cell plate layer 5 that is to be connected to the sidewall of the conductor plug 7A filled with tungsten. Here, the second insulating film 11 of a larger etchability is formed on the upper surface of the cell plate layer 5, and the third insulating film 13 of a smaller etchability, i.e. a lower etch rate, is formed on the upper surface of the first insulating film Next, the connecting hole 12 is formed using anisotropic etching, then, the laminate is immersed in a chemical solution that etches only the second insulating film 11 on the upper surface of the cell plate layer 5 to retract the second insulating film 11 in the lateral direction shown by arrows until the upper surface of the cell plate layer 5 is exposed (see FIG. 2A).

Next, a barrier metal 6 is formed on the inner wall of the connecting hole 12 using the CVD method, which excels in coverage, then, the connecting hole 12 is filled with a conductor to form the conductor plug 7A. At this time, the conductor plug 7A contacts substantially not only with the sidewall but also with the upper surface of the cell plate layer 5 (see FIG. 2B). Therefore, the contact area increases and the resistance lowers. In this structure, since the third insulating film 13 is not retracted in the lateral direction, the upper dimension of the connecting hole 12 is not changed.

According to the Second Embodiment, as described above, among a plurality of insulating films, an insulating film contacting on the upper surface of the cell plate layer is selectively retracted in the lateral direction to increase the contact area between the cell plate layer and the conductor plug filled with tungsten, thus lowering contact resistance.

Third Embodiment

FIGS. 3A and 3B are schematic cross-sectional views showing a conductor plug filled with a conductor, and a conductor layer that is connected to the sidewall of the conductor plug according to a Third Embodiment of the present invention. FIG. 3A is a sectional view when the conductor plug is not yet formed by filling the conductor, and FIG. 3B is a sectional view after the conductor plug has been formed.

In FIGS. 3A and 3B, reference numeral 14 indicates a fourth insulating film formed underneath the first insulating film 10. Other components are same as the components shown in FIG. 1. Here, the first insulating film 10 has a larger etchability, i.e. a higher etch rate, than the second and fourth insulating films 11 and 14, respectively.

In the Third Embodiment, the first insulating film beneath the lower surface of the conductor layer 5 is selectively retracted to expose the surface of the conductor layer 5 to increase the contact area.

Next, the manufacturing process of the Third Embodiment will be described below.

First, different insulating films are laminated beneath the lower surface of the cell plate layer 5 that is to be connected to the sidewall of the conductor plug 7A filled with tungsten. Here,the first insulating film 10 of a larger etchability is formed underneath the cell plate layer 5, and the fourth insulating film 14 of a smaller etchability is formed underneath the first insulating film 10.

Next, a second insulating film 11 is laminated on the upper surface of the cell plate 5, and a connecting hole 12 is formed using anisotropic etching, then, the laminate is immersed in a chemical solution that etches only the first insulating film 10 underneath the cell plate layer 5 to retract the first insulating film 10 in the lateral direction shown by arrows until the lower surface of the cell plate layer 5 is exposed (see FIG. 3A).

Next, a barrier metal 6 is formed on the inner wall of the connecting hole 12 using the CVD method, which excels in coverage, then, the connecting hole 12 is filled with tungsten to form the conductor plug 7A. At his time, the conductor plug 7A contacts substantially not only with the sidewall but also with the under surface of the cell plate layer 5 (see FIG. 3B). Therefore, the contact area increases and the resistance lowers. In this structure, since the fourth insulating film 14 is not retracted in the lateral direction, the upper dimension of the connecting hole 12 is not changed.

According to the Third Embodiment, as described above, among a plurality of insulating films, an insulating film contacting on the lower surface of the cell plate layer is selectively retracted in the lateral direction to increase the contact area between the cell plate layer and the conductor plug filled with tungsten, thus lowering contact resistance.

Fourth Embodiment

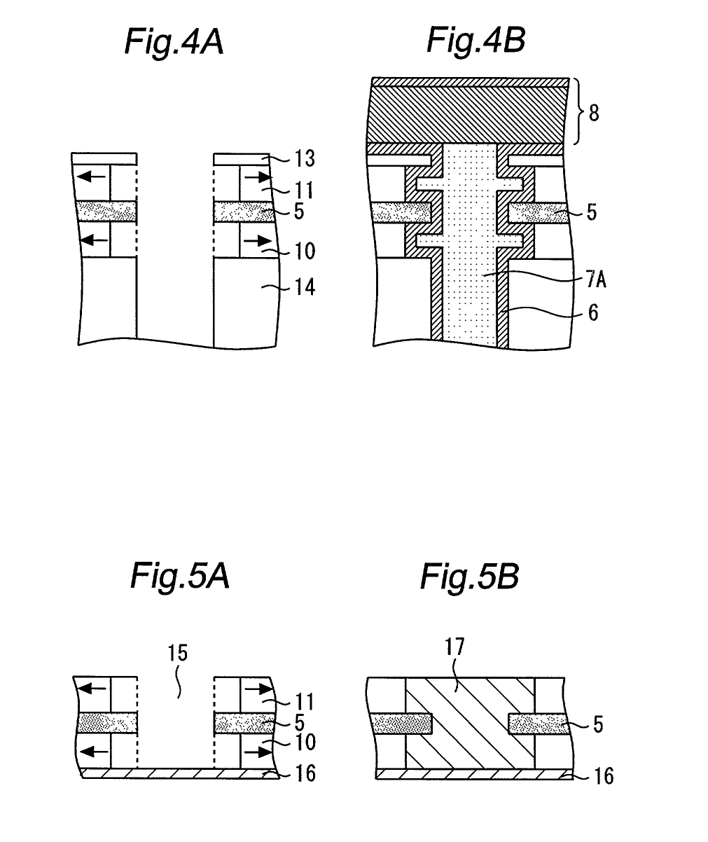

FIGS. 4A and 4B are schematic sectional views showing a conductor plug filled with a conductor, and a conductor layer that is connected to the sidewall of the conductor plug according to a Fourth Embodiment of the present invention. FIG. 4A is a sectional view when the conductor plug is not yet formed by filling the conductor, and FIG. 4B is a sectional view after the conductor plug has been formed

In FIGS. 4A and 4B, insulating films 14 and 10 are formed under the cell plate layer 5, and insulating films 11 and 13 are formed on the cell plate layer 5. Here, the insulating films 10 and 11 have a larger etchability, i.e. a higher etch rate, than the insulating films 14 and 13, respectively.

In the Fourth Embodiment, among a plurality of insulating films, the first and the second insulating films on the upper and lower surfaces of the conductor layer 5 are selectively retracted to expose the surface of the conductor layer to increase the contact area.

Next, the manufacturing process of the Fourth Embodiment will be described below.

First, different insulating films are laminated on and under the cell plate layer 5 that is to be connected to the sidewall of the conductor plug 7A filled with tungsten. Here, the first insulating film 10 and the second insulating film 11 of a larger etchability are formed underneath and on the upper surface of the cell plate layer 5, respectively, and the fourth insulating film 14 and the third insulating film 13 of a smaller etchability are formed underneath the first insulating film 10 and on the upper surface of the second insulating film 11, respectively.

Next, a connecting hole 12 is formed using anisotropic etching, then, the laminate is immersed in a chemical solution that etches only the first insulating film 10 underneath the cell plate layer 5 and the second insulating film 11 on the upper surface of the cell plate layer 5 to retract the first and second insulating films 10 and 11 in the lateral direction shown by arrows until the upper and lower surfaces of the cell plate layer 5 are exposed (see FIG. 4A).

Next, a barrier metal 6 is formed on the inner wall of the connecting hole 12 using the CVD method, which excels in coverage, then, the connecting hole 12 is filled with tungsten to form the conductor plug 7A. At this time, the conductor plug 7A contacts substantially not only with the sidewall but also with the upper and lower surfaces of the cell plate layer 5 (see FIG. 4B). Therefore, the contact area increases and the resistance lowers. In this structure, since the third insulating film 13 above the cell plate layer 5 and the fourth insulating film 14 under the cell plate layer 5 are not retracted in the lateral direction, the upper and bottom dimension of the connecting hole 12 is not changed.

According to the Fourth Embodiment, as described above, among a plurality of insulating films, insulating films contacting on the upper and under surfaces of the cell plate layer are selectively retracted in the lateral direction to increase the contact area between the cell plate layer and the conductor plug filled with tungsten, thus lowering contact resistance.

Fifth Embodiment

FIGS. 5A and 5B are schematic cross-sectional views showing a buried wiring filled with a conductor, and a conductor layer that is connected to the sidewall of the buried wiring according to a Fifth Embodiment of the present invention. FIG. 5A is a sectional view when the conductor plug is not yet formed by filling the conductor, and FIG. 5B is a sectional view after the buried wiring has been formed.

In FIGS. 5A and 5B, reference numeral 15 is a grove pattern as a through hole for a buried wiring, 16 is an etching stopper film, and 17 is a buried wiring as a conducting member. Here, the first and second insulating films 10 and 11 have a large etchability, i.e. a higher etch rate.

In the Fifth Embodiment, insulating films 10 and 11 contacting the conducting layer 5 are selectively retracted to expose the surface of the conductor layer 5 to increase the contact area.

Next, the manufacturing process of the Fourth Embodiment will be described below.

First, the first and second insulating films 10 and 11 of a large etchability are laminated on and under the cell plate layer 5 that is to be connected to a buried wiring 17, respectively, and an etching stopper film 16 to stop anisotropic etching is formed underneath the first insulating film 10 under the cell plate layer 5, i.e. on the upper surface of a semiconductor substrate (not shown).

Next, a groove pattern 15 for a buried wiring is formed using anisotropic etching, then, the laminate is immersed in a chemical solution that etches only the first insulating film 10 underneath the cell plate layer 5 and the second insulating film 11 on the upper surface of the cell plate layer 5 to retract the first and second insulating films 10 and 11 in the lateral direction shown by arrows until the upper and lower surfaces of the cell plate layer 5 are exposed (see FIG. 5A).

Next, a buried wiring 17 is formed by burying a conductor in the groove pattern 15 using the Damascene method for example. At this time, the buried wiring 7 contacts substantially not only with the sidewall but also with the upper and lower surfaces of the cell plate layer 5 (see FIG. 5B). Therefore, the contact area increases and the resistance lowers.

According to the Fifth Embodiment, as described above, a plurality of insulating films contacting the upper and under surfaces of the cell plate layer are selectively retracted in the lateral direction to increase the contact area between the cell plate layer and the buried wiring, thus lowering contact resistance.

Although the above-described embodiments have been described as applied to semiconductor devices including semiconductor integrated circuit devices, the present invention is not limited to these devices, but the same effect can be obtained when applied to, for example, other contact structures, and a method for forming such contact structures.

The features and the advantages of the present invention as described above may be summarized as follows.

According to one aspect of the invention, in a semiconductor device, a through hole is formed through an insulating film and a conductor layer so as to expose a circumference of the side surface of said conductor layer, and a conducting member is provided by filling said through hole with a conductor. Accordingly, the contact area between the conductor layer and the conducting member is increased and the contact resistance is lowered, and the effect of obtaining stable and reliable semiconductor devices can be achieved.

In another aspect, in the semiconductor device, at least one of upper and lower surfaces of the conductor layer that contacts to the through hole is exposed. Accordingly, the effect of increasing the contact area between the conductor layer and the conducting member and lowering the contact resistance can be obtained.

In another aspect, in the semiconductor device, the conducting member is a conductor plug that is connected to the conductor layer. Accordingly, the effect of preventing poor contacting can be obtained.

In another aspect, in the semiconductor device, the through hole is a connecting hole for connecting the conductor layer to a side wall of the conductor plug. Accordingly, the effect of increasing the contact area between the conductor layer and the conducting member and lowering the contact resistance can be obtained.

In another aspect, the semiconductor device further comprises a stopper film provided between the semiconductor substrate and the insulating film. Accordingly, it is useful to form buried wirings of semiconductor devices.

In another aspect, in the semiconductor device, the conducting member is a buried wiring connected to the conductor layer. Accordingly, the effect of increasing the contact area between the conductor layer and the buried wiring and lowering the contact resistance can be obtained, and it contributes to the manufacture of stable and reliable semiconductor devices.

In another aspect, in the semiconductor device, the through hole has a groove pattern so as to connect the conductor layer to a sidewall of the buried wiring. Accordingly, the effect of increasing the contact area between the conductor layer and the buried wiring and lowering the contact resistance can be obtained.

According to another aspect of the invention, in a method of manufacturing a semiconductor device, a first insulating film is formed on a semiconductor substrate. A conductor layer is formed on said first insulating film. A second insulating film is formed on said conductor layer. A through hole is formed passing through said second insulating film, said conductor layer, and said first insulating film. At least one of said first and second insulating films is retracted to expose said conductor layer; and said through hole is filled with a conductor to form a conducting member. Accordingly, the effect of increasing the contact area between the conductor layer and the conducting member and lowering the contact resistance can be obtained, and it contributes to the manufacture of stable and reliable semiconductor devices.

In another aspect, in the method of manufacturing a semiconductor device, the second insulating film has a higher etchability than the first insulating film, and the second insulating film is retracted to expose an upper surface of the conductor layer. Accordingly, the effect of increasing the contact area between the conductor layer and the conducting member and lowering the contact resistance can be obtained.

In another aspect, in the method of manufacturing a semiconductor device, a third insulating film is formed on the second insulating film, and the second insulating film is retracted to expose an upper surface of the conductor layer. Accordingly, the effect of increasing the contact area between the conductor layer and the conducting member and lowering the contact resistance can be obtained.

In another aspect, in the method of manufacturing a semiconductor device, a fourth insulating film is previously formed underneath the first insulating film, the first insulating film has a higher etchability than the second and fourth insulating films, and the first insulating film is retracted to expose the lower surface of the conductor layer. Accordingly, the effect of increasing the contact area between the conductor layer and the conducting member and lowering the contact resistance can be obtained.

In another aspect, in the method of manufacturing a semiconductor device, a fourth insulating film is previously formed underneath the first insulating film, and the first and second insulating films are retracted to expose the upper and lower surfaces of the conductor layer. Accordingly, the effect of increasing the contact area between the conductor layer and the conducting member and lowering the contact resistance can be obtained.

In another aspect, in the method of manufacturing a semiconductor device, the conducting member is a conductor plug that is connected to the conductor layer. Accordingly, the effect of preventing poor contacting can be obtained.

In another aspect, in the method of manufacturing a semiconductor device, the through hole is a connecting hole for connecting the conductor layer to the sidewall of the conductor plug. Accordingly, the effect of increasing the contact area between the conductor layer and the conducting member and lowering the contact resistance can be obtained.

In another aspect, in the method of manufacturing a semiconductor device, an etching stopper film is previously formed on the semiconductor substrate prior to the formation of the first insulating film, the first and second insulating films have a high etchability, and the first and second insulating films are retracted to expose the upper and lower surfaces of the conductor layer. Accordingly, the effect of increasing the contact area between the conductor layer and the buried wiring and lowering the contact resistance can be obtained, and it contributes to the manufacture of stable and reliable semiconductor devices.

In another aspect, in the method of manufacturing a semiconductor device, the conducting member is a buried wiring connected to the conductor layer. Accordingly, the effect of increasing the contact area between the conductor layer and the buried wiring and lowering the contact resistance can be obtained, and it contributes to the manufacture of stable and reliable semiconductor devices.

In another aspect, in the method of manufacturing a semiconductor device, the through hole has a groove pattern so as to connect the conductor layer to a side wall of the buried wiring. Accordingly, the effect of increasing the contact area between the conductor layer and the buried wiring and lowering the contact resistance can be obtained.

According to another aspect of the invention, a contact structure comprises a substrate and an insulating film formed on the substrate. A through hole is formed through said insulating film and said conductor layer so as to expose a circumference of the side surface of said conductor layer, and a conducting member is formed by filling said through hole with a conductor. Accordingly, the effect of increasing the contact area between the conductor layer and the conducting member and lowering the contact resistance can be obtained, and it contributes to the manufacture of stable and reliable contact structure.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2000-39307, filed on Dec. 25, 2000 including specification, claims, drawings and summary, on which the Convention priority of the present application is based, are incorporated herein by reference in its entirety.

1. A semiconductor device comprising:
a semiconductor substrate;
an insulating film formed on the semiconductor substrate;
a conductor layer formed in said insulating film;
a through hole formed through said insulating film and said conductor layer so as to expose a circumference of the side surface of said conductor layer; and
a conducting member formed by filling said through hole with a conductor.

2. The semiconductor device according to claim 1, wherein said conducting member is a conductor plug that is connected to said conductor layer.

3. The semiconductor device according to claim 1, wherein at least one of the upper and lower surfaces of said conductor layer is exposed to contact said conducting member.

4. The semiconductor device according to claim 3, wherein said conducting member is a conductor plug that is connected to said conductor layer.

5. The semiconductor device according to claim 1, further comprising an etching stopper film provided between said semiconductor substrate and said insulating film.

6. The semiconductor device according to claim 5, wherein said through hole has a groove pattern and said conducting member is a buried wiring connected to said conductor layer.

7. A method of manufacturing a semiconductor device, comprising the steps of:
forming a first insulating film on a semiconductor substrate;
forming a conductor layer on said first insulating film;
forming a second insulating film on said conductor layer;
forming a through hole passing through said second insulating film, said conductor layer, and said first insulating film;
retracting at least one of said first and second insulating films in said through hole to expose said conductor layer; and
filling said through hole with a conductor to form a conducting member.

8. The method of manufacturing a semiconductor device according to claim 7, wherein said conducting member is a conductor plug that is connected to said conductor layer.

9. The method of manufacturing a semiconductor device according to claim 7, wherein an etching stopper film is previously formed on said semiconductor substrate prior to formation of said first insulating film.

10. The method of manufacturing a semiconductor device according to claim 9, wherein said through hole has a groove pattern and said conducting member is a buried wiring connected to said conductor layer.

11. The method of manufacturing a semiconductor device according to claim 7, wherein said second insulating film has a higher etchability than said first insulating film, and said second insulating film is retracted to expose an upper surface of said conductor layer.

12. The method of manufacturing a semiconductor device according to claim 11, wherein said conducting member is a conductor plug that is connected to said conductor layer.

13. The method of manufacturing a semiconductor device according to claim 7, wherein a third insulating film is formed on said second insulating film, and said second insulating film is retracted to expose an upper surface of said conductor layer.

14. The method of manufacturing a semiconductor device according to claim 13, wherein said conducting member is a conductor plug that is connected to said conductor layer.

15. The method of manufacturing a semiconductor device according to claim 7, wherein a fourth insulating film is previously formed underneath said first insulating film, and said first insulating film has a higher etchability than said second and fourth insulating films, and said first insulating film is retracted to expose a lower surface of said conductor layer.

16. The method of manufacturing a semiconductor device according to claim 15, wherein said conducting member is a conductor plug that is connected to said conductor layer.

17. The method of manufacturing a semiconductor device according to claim 7, wherein a fourth insulating film is previously formed underneath said first insulating film, and a third insulating film is formed on said second insulating film, and said first and second insulating films have a higher etchability than said third and fourth insulating films, and said first and second insulating films are retracted to expose the upper and lower surfaces of said conductor layer.

18. The method of manufacturing a semiconductor device according to claim 17, wherein said conducting member is a conductor plug that is connected to said conductor layer.

19. A method of manufacturing a contact structure, comprising the steps of:
forming a first insulating film on a substrate;
forming a conductor layer on said first insulating film;
forming a second insulating film on said conductor layer;
forming a through hole passing through said second insulating film, said conductor layer, and said first insulating film;
retracting at least one of said first and second insulating films in said through hole to expose said conductor layer; and
filling said through hole with a conductor to form a conducting member.

20. A contact structure, comprising:
a substrate;
an insulating film formed on the substrate;
a conductor layer formed in said insulating film;
a through hole formed through said insulating film and said conductor layer so as to expose a circumference of the side surface of said conductor layer; and
a conducting member formed by filling said through hole with a conductor.
